(19) United States
(12) Patent Application Publication
(10) Pub. No.: US 2023/0198058 A1
(43) Pub. Date: Jun. 22, 2023

(54) EMBEDDED BATTERIES WITHIN GLASS CORES OF PACKAGE SUBSTRATES

(71) Applicant: Intel Corporation, Santa Clara, CA (US)

(72) Inventors: Veronica Strong, Hillsboro, OR (US); Telesphor Kamgaing, Chandler, AZ (US); Neelam Prabhu Gaunkar, Chandler, AZ (US); Georgios Dogiamis, Chandler, AZ (US); Aleksandar Aleksov, Chandler, AZ (US); Brandon Rawlings, Chandler, AZ (US)

(21) Appl. No.: 17/556,784

(22) Filed: Dec. 20, 2021

(51) Int. Cl. H01M 50/117; H01L 23/58

(52) U.S. Cl. CPC H01M 50/117; H01L 23/58

(57) ABSTRACT

Embedded batteries within glass cores are disclosed. Example apparatus include a glass core layer having opposing first and second surfaces, the glass core layer including a cavity extending from the first surface toward the second surface, and a battery including a first conductive material positioned in the cavity, a second conductive material positioned in the cavity, and an electrolyte to separate the first conductive material from the second conductive material.

### FIELD OF THE DISCLOSURE

This disclosure relates generally to integrated circuit packaging and, more particularly, to embedded batteries within glass cores of package substrates.

### BACKGROUND

Integrated circuit (IC) chips and/or semiconductor dies are routinely connected to larger circuit boards such as motherboards and other types of printed circuit boards (PCBs) via a package substrate. As IC chips and/or dies reduce in size and interconnect densities increase, alternatives to traditional substrate layers are needed for providing stable transmission of high frequency data signals between different circuitry and/or increased power delivery.

### BRIEF DESCRIPTION OF THE DRAWINGS

FIG. 1 is a cross-sectional side view of an example IC package constructed in accordance with teachings disclosed herein.

FIG. 2 is another cross-sectional top view of the example IC package of FIG. 1 taken along line 2-2.

FIG. 3 is a top plan view of the example IC package of FIG. 1.

FIG. 4 is a top plan view of an example IC package that illustrates example batteries in parallel.

FIG. 5 is a top plan view of an example IC package that illustrates example batteries in series.

FIG. 6 is a cross-sectional side view of another example IC package constructed in accordance with teachings disclosed herein.

FIG. 7 is a cross-sectional top view of the example IC package of FIG. 6 taken along the line 7-7.

FIG. 8 is a cross-sectional side view of another example IC package constructed in accordance with teachings disclosed herein.

FIG. 9 is a bottom plan view of the example IC package of FIG. 8.

FIG. 10 is a top plan view of the example IC package of FIG. 8.

FIGS. 11 and 12 are flowcharts representative of an example method of manufacturing an example IC package disclosed herein.

FIGS. 13-24 depict the example IC package of FIGS. 6 and 7 at various manufacturing stages corresponding to the example methods of FIGS. 11 and 12.

FIG. 25 is a wafer and dies that may be included in the example IC packages of FIGS. 1-10 constructed in accordance with teachings disclosed herein.

FIG. 26 is a cross-sectional side view of an IC device that may be included in the example IC packages of FIGS. 1-10 constructed in accordance with teachings disclosed herein.

FIG. 27 is a cross-sectional side view of an IC package that may correspond to the example IC packages of FIGS. 1-10 constructed in accordance with teachings disclosed herein.

FIG. 28 is a cross-sectional side view of an IC device assembly that may include the example IC packages of FIGS. 1-10 constructed in accordance with teachings disclosed herein.

FIG. 29 is a block diagram of an example electrical device that may include the example IC packages of FIGS. 1-10 constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

### DETAILED DESCRIPTION

Highly integrated microelectronic systems are needed to satisfy the continuous increase in data demand as well as the overall user experience. This has not only led to new integration strategies involving die disaggregation and re-stitching of technologies (e.g. semiconductor dies) from different nodes and processes, but also to an increase in the number of dies that are to be co-integrated in close proximity of each other on the same package substrate. Assembling multiple dies using 3D-IC technologies such as Foveros and hybrid bonding leads to smaller footprints. However, such IC packages come with thermal management challenges that only grow exponentially as the number of dies or active device layers in the 3D-IC stack-up increases. As more dies are included in a package, the thermal challenges can be at least partially alleviated by spreading out the dies across a large package substrate. In today's high speed systems, latency, bandwidth density, and power efficiency determine the relative locations of high-speed dies associated with computing and storage. For example, high-speed dies are typically on the same side of the package substrate as memory dies because going through an organic package core is detrimental to at least one of bandwidth density or power efficiency. However, placing separate dies on the same side of the package substrate has the inherent drawback of contributing to an increase in the package size and low yield from substrate manufacturing and potential assembly.

One option that is being considered to address present challenges is the implementation of glass cores in package substrates instead of the copper clad laminate (CCL) cores typically used in many existing IC packages manufactured today. By using laser-assisted etching, crack free, high-density via drills (e.g., hollow shapes, openings, channels, etc.) can be formed into a glass substrate that may then serve as the core for a package substrate. Different process parameters can be adjusted to achieve drills of various shapes and depths, thereby opening the door for innovative devices, architectures, processes and designs in glass.

Furthermore, drills or openings produced in a glass core can be filled with materials other than metals to achieve other purposes beyond simple metal interconnects that route signals through a package substrate. More particularly, examples disclosed herein include core-embedded thin film batteries to power small discrete units or devices (e.g., a light emitting diode (LED)), integrated passive devices, and/or other integrated components (e.g., semiconductor dies). In some examples, solid state electrolyte (e.g., lithium-based batteries are implemented to provide high operating voltage, high specific capacity, and long cycle life. The synthesis of lithium-based batteries typically requires substrates that can withstand high temperature processing, which has limited the incorporation of such batteries into organic packaging or thin films. However, by implementing batteries in glass core substrates, as disclosed herein, these concerns are overcome because glass can handle high temperature processing. Furthermore, implementing embedded batteries within glass cores can provide performance improvements due to the properties of glass as compared with the properties of traditional organic substrates.

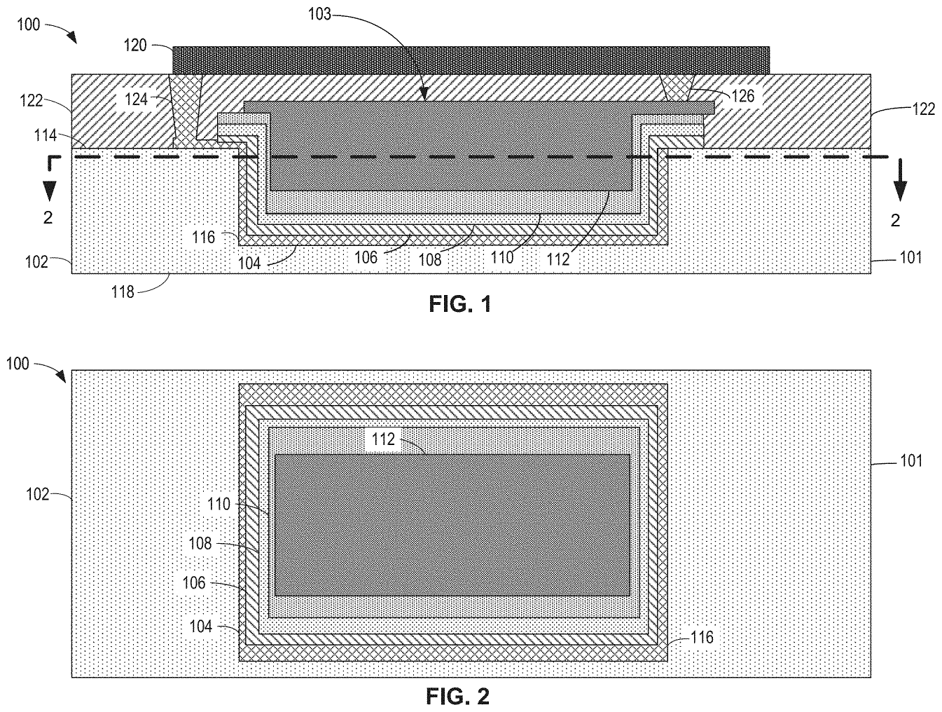

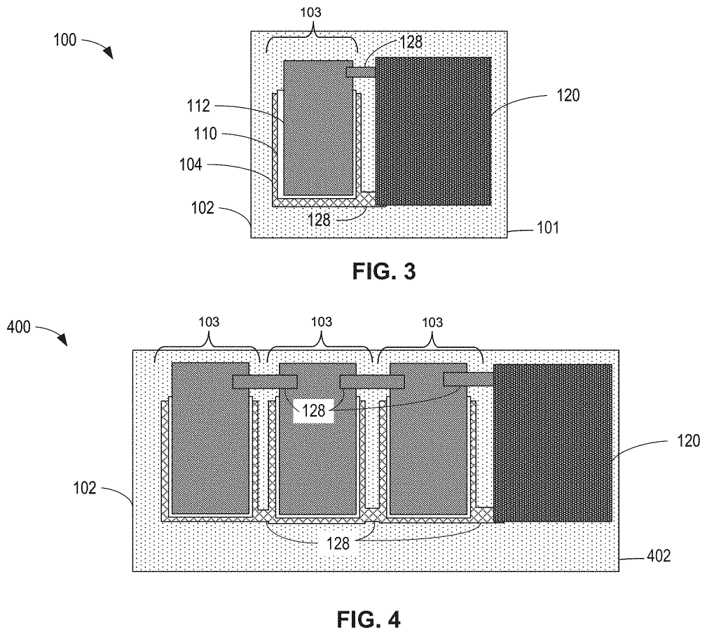

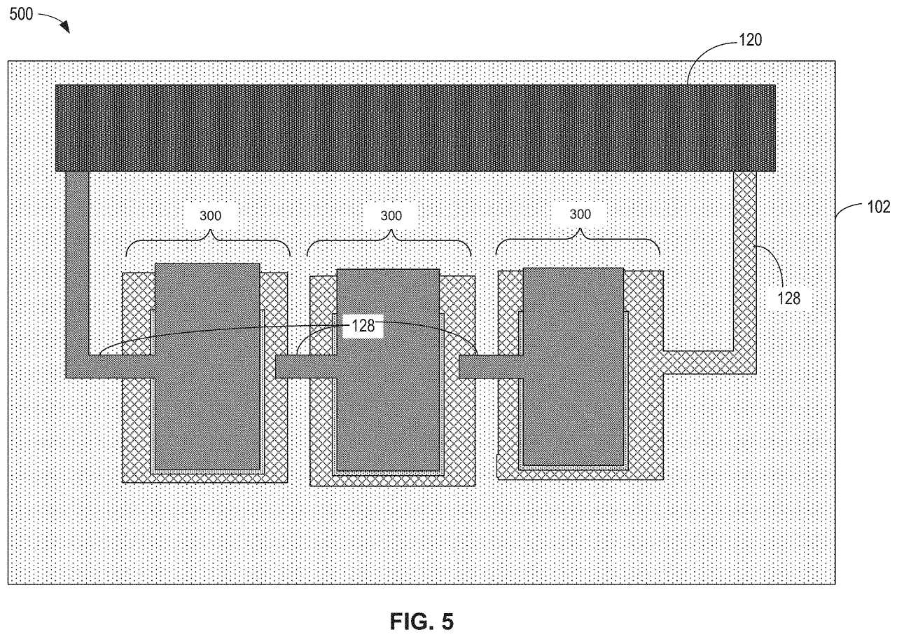

FIG. 1 is a cross-sectional side view of an example IC package 100 including an example package substrate 101 constructed in accordance with teachings disclosed herein. FIG. 2 is a cross-sectional top view of the example IC package 100 taken along line 2-2 of FIG. 1. FIG. 3 is a top plan view of the example IC package 100 of FIGS. 1 and 2. While examples are described with respect to a glass core 102 of a package substrate 101 within an IC package 100, teachings disclosed herein can be implemented in connection with any glass substrate regardless of whether the substrate is used as a core or a package substrate. As shown in the illustrated example of FIG. 1, the IC package 100 includes an example glass core layer 102 (also referred to herein simply as a glass core) and a battery 103 at least partially embedded in the glass core 102. In this example, the battery 103 is made up of a plurality of layers 104, 106, 108, 110, 112 of battery materials provided on a first surface 114 of the glass core 102 and within a cavity 116 of a blind via within the glass core 102. In some examples, some or all of the layers 104, 106, 108, 110, 112 are contained within the cavity 116 without being deposited on or extend beyond a plane defined by the outer surface 114 of the glass core 102. As shown in the illustrated examples, the layers 104, 106, 108, 110, 112 include a series of materials that overlap one another on the first surface 114 and within the cavity 116. In some examples, the layers 104, 106, 108, 110, 112 are deposited as films that conformally coat the glass core 102 (and/or any underlying (previously deposited) layers 104, 106, 108, 110, 112). Such conformal coatings may be achieved using any suitable deposition technique (e.g., atomic layer deposition (ALD), chemical vapor deposition (CVD), spin coating, spray coating, metal sputtering, etc.). The cavity 116 extends from the first surface 114 to an opposing second surface 118 of the glass core layer 102. In some examples, the cavity 116 is an opening extending into the glass core layer 102 from the first surface 114. That is, in this example, the cavity 116 extends in a direction transverse to the first surface 114 of the glass core layer 102. The layers 104, 106, 108, 110, 112 are positioned (e.g., embedded) in the cavity 116 such that a surface (e.g., wall) of the cavity 116 is in contact with and/or adjacent to the anode current collector 104. In some examples, the layers 104, 104, 108, 110, 112 line walls of the cavity 116. Further, in some examples, the position of the layers 104, 106, 108, 110, 112 within the cavity 116 results in the layers closest to the walls of the cavity 116 surrounding the other layers closer to a middle of the cavity 116. As shown in FIG. 2, the cavity 116 has a generally rectangular shape. However, the cavity 116 can be a groove, an elongated trench or channel, and/or be in any suitable shape and/or have any suitable dimensions.

The plurality of layers 104, 106, 108, 110, 112 of the battery 103 correspond to an anode current collector 104, an anode layer 106, an electrolyte 108, a cathode layer 110, and a cathode current collector 112. The anode current collector 104 and the cathode current collector 112 are positioned on opposite ends of the stack of layers with the anode layer 106 adjacent the anode current collector 104, the cathode layer 110 adjacent the cathode current collector 112, and the electrolyte 108 between the anode layer 106 and cathode layer 110. In the illustrated examples of FIGS. 1-3, the anode current collector 104 is positioned closest to the glass core 102 with the cathode current collector 112 positioned the farthest from the glass core 102. In other examples, the ordering of the layers can be reversed such that the cathode current collector 112 is positioned closest to the glass core 102 with the anode current collector 104 positioned the farthest from the glass core 102. Both the anode current collector 104 and the cathode current collector 112 are composed of a conductive material (e.g., copper (Cu), aluminum (Al), platinum (Pt), nickel (Ni), etc.). In some examples, the same material is used to implement both the anode current collector 104 and the cathode current collector 112. In other examples, a different material is used for each of the anode current collector 104 and the cathode current collector 112.

In this example, the battery 103 is a lithium-based battery. Accordingly, in this example, the anode layer 106 is composed of lithium (Li) lithium oxide (Li₂O), and/or graphite or carbon (C) based materials. Further, the cathode layer 110 is composed of any suitable material capable of transporting positive lithium (Li⁺) ions (e.g., lithium cobalt oxide (LiCoO₂ (LCO)), lithium manganese oxide (LiMn₂O₃), etc.).

The electrolyte 108 (also referred to herein as a separator) electrically isolates (e.g., separates, positioned between) the anode layer 106 from the cathode layer 110. Further, the electrolyte 108 is composed of a material that enables lithium ions to flow or be transported (e.g., ion diffusion) between the anode layer 106 and the cathode layer 110. More particularly, in some examples, the electrolyte 108 is composed of a solid state electrolyte such as lithium phosphorous oxynitride (LiPON). In the illustrated example of FIGS. 1-3, the electrolyte 108 is a solid state electrolyte. In other examples, the electrolyte 108 can be a liquid electrolyte coated on a separator film that is contained within the cavity 116 of the glass core 102.

In the example IC package 100 of FIGS. 1-3, the battery 103 provides power to an electrical device 120. In some examples, the electrical device 120 is discrete unit or an integrated passive device. In some examples, the electrical device 120 is included in a semiconductor die or IC chip mounted on a package substrate containing the glass core 102 (and the battery 103). In other examples, the electrical device 120 is incorporated into the package substrate containing the glass core 102 but is positioned within build-up layers external to the glass core 102. Although one electrical device 120 is shown, in other examples, the battery 103 may provide power to multiple different electrical devices.

As shown in the illustrated example, the battery 103 is electrically isolated or separated from the electrical device 120 by a dielectric 122. In some examples, the dielectric 122 enclosed or covers portions of the battery 103 that are not otherwise directly enclosed by the glass core 102. In some examples, the dielectric 122 is composed of multiple layers of organic laminate dielectric (e.g., laminated epoxy layers), also known as layers of build-up film. The electrical device 120 is electrically coupled to both the anode current collector 104 and the cathode current collector 112 through corresponding conductive vias 124, 126 that extend through the dielectric 122 towards the electrical device 120. In some examples, the electrical device 120 is positioned to be in alignment with the battery 103 in a direction normal to the first surface 114 of the glass substrate such that the conductive vias 124, 126 may extend directly towards the device 120. herein some examples, the electrical device 120 can be electrically connected to the vias 124, 126 through the use of via pads and/or micro solder balls. In some examples, as shown in FIG. 3, the electrical device 120 may be offset relative to the location of the battery 103. In some such examples, one or more conductive traces or routing 128 in a plane of the dielectric 122 is provided to electrically couple the conductive vias 124, 126 to the electrical device 120.

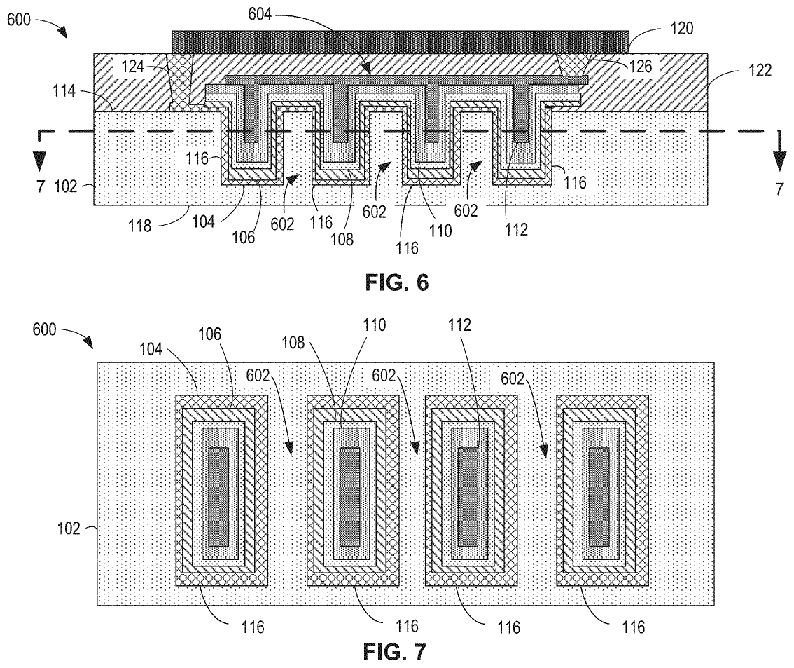

FIG. 4 is a plan view of another example IC package 400 including an example package substrate 402 constructed in accordance with teachings disclosed herein. The example IC package 400 of FIG. 4 is similar to the example IC package 100 of FIG. 3, but, instead, the example IC package includes multiple batteries 300 embedded in the glass core 102. In this example, the multiple batteries 300 are connected in parallel to the electrical device 120 through different segments of traces or routing 128 extending between adjacent ones of the batteries 300 and between the batteries 300 and the electrical device 120. The example IC package 400 includes multiple cavities 116 in the first surface 114 separated by portions of the glass core layer 102. Each one of the batteries 300 is associated with different ones of the multiple cavities 116 such that each one of the batteries 300 is positioned (e.g., embedded) with the glass core layer 102. Although three batteries 300 are shown in FIG. 4, any suitable number of batteries 300 (e.g., 1, 2, 3, 4, 5, etc.) in any suitable arrangement may be implemented.

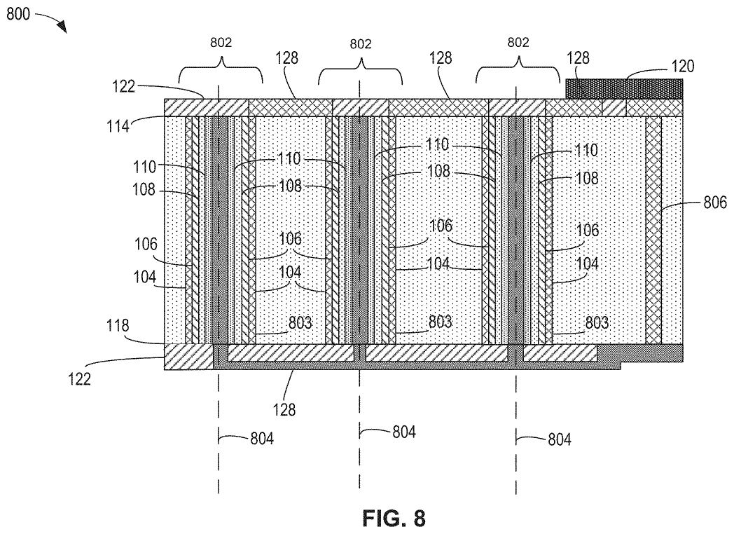

FIG. 5 is a plan view of an example IC package 500. The example IC package 500 of FIG. 5 is similar to the example IC package 400 of FIG. 4 with multiple batteries 300 providing power to the electrical device 120. However, unlike in FIG. 4, the example IC package 500 of FIG. 5 includes the multiple batteries 300 connected in series to the device 120. That is, in this example, the anode current collector of one battery 300 is electrically coupled to the cathode current collector of an adjacent battery 300 in the series. Although three batteries 300 are shown in FIG. 5, any suitable number of batteries 300 (e.g., 1, 2, 3, 4, 5, etc.) in any suitable arrangement may be implemented. For instance, a combination of series and parallel embedded battery configurations is possible in accordance with teachings disclosed herein.

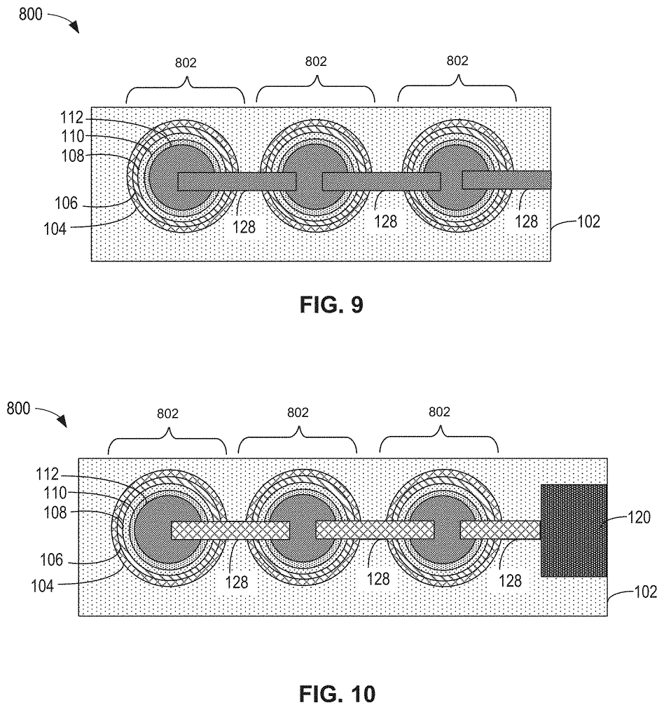

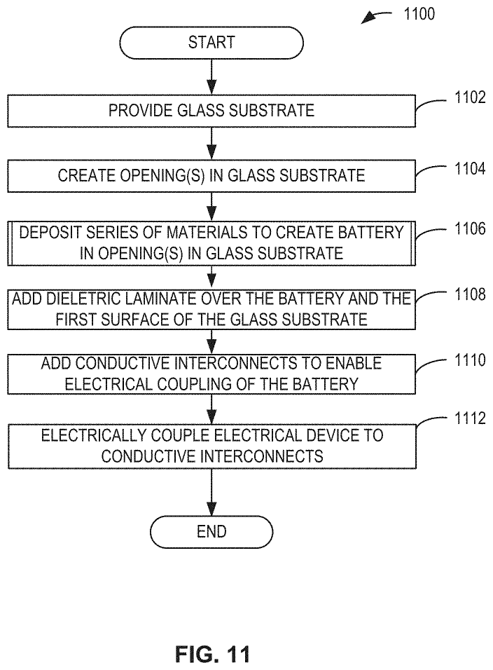

FIG. 6 is a cross-sectional side view of an example IC package 600 constructed in accordance with teachings disclosed herein. FIG. 7 is a cross-sectional top view of the example IC package 600 taken along the line 7-7 of FIG. 6. The example IC package 600 of FIGS. 6 and 7 is similar to the example IC package 100 of FIGS. 1-3 except that the IC package 600 includes multiple cavities 116 distributed along the first surface 114 of the glass core layer 102 and separated by portions 602 of the glass core layer 102. Specifically, in the example IC package 600, the layers 104, 106, 108, 110, 112 are positioned (e.g., embedded) in different ones of the multiple cavities 116. Unlike the discrete batteries 300 shown in the illustrated examples of FIGS. 4 and 5, where each battery 300 is embedded in a separate cavity, in the illustrated example of FIGS. 6 and 7, the example battery 604 extends across the multiple cavities 116. More particularly, as shown in the illustrated example, each of the layers 104, 106, 108, 110, 112 of the battery 604 extend continuously between different ones of the multiple cavities 116 by lining the walls of the cavities 116 and extending over the first surface 114 of the glass core layer 102 associated with the portions 602 of the glass core layer 102 separating the different cavities 116. Further, in this example, the cathode current collector 112 covers the other layers 104, 106, 108, 110 of the battery 604 such that the cathode current collector 112 extends continuously in a straight line across the multiple cavities 116. Implementing the example battery 604 of FIGS. 6 and 7 across multiple cavities 116, as shown in the illustrated examples, increases the surface area of the anode and cathode layers 106, 110, thereby increasing the operating window of the embedded battery 604. Unlike what is shown in FIG. 6, in some examples, the upper surface of the portions 602 of the glass core 102 may be recessed relative to the first surface 114 such that one or more of the layers 104, 106, 108, 110, 112 remains below a plane defined by the first surface 114 as they extend across and between the different cavities 116.

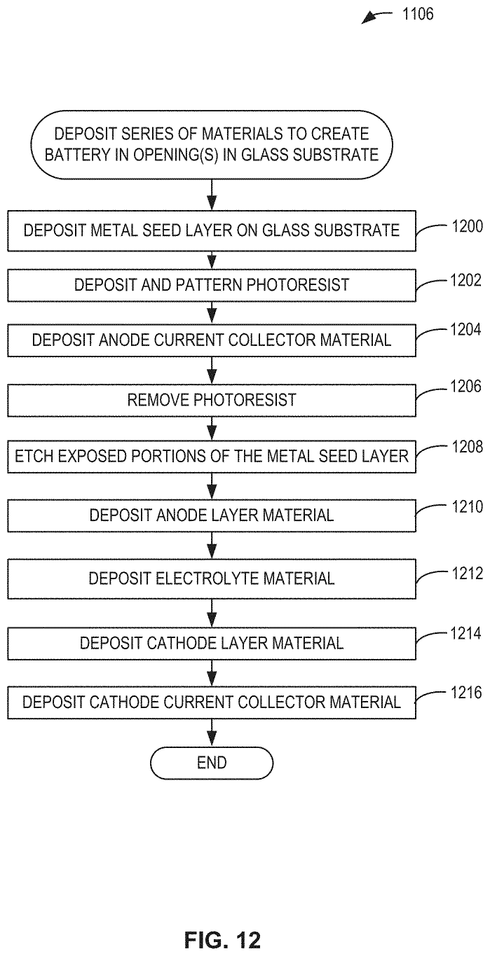

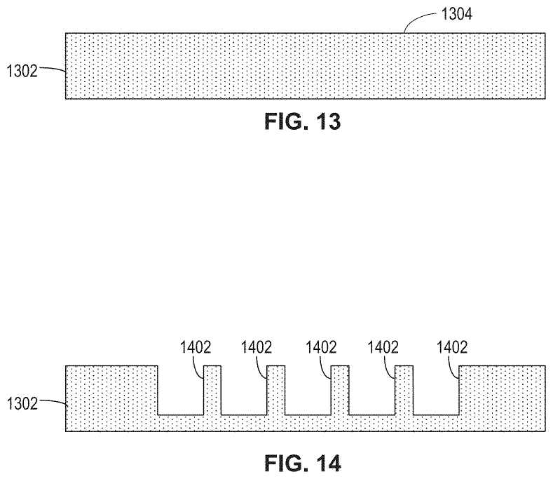

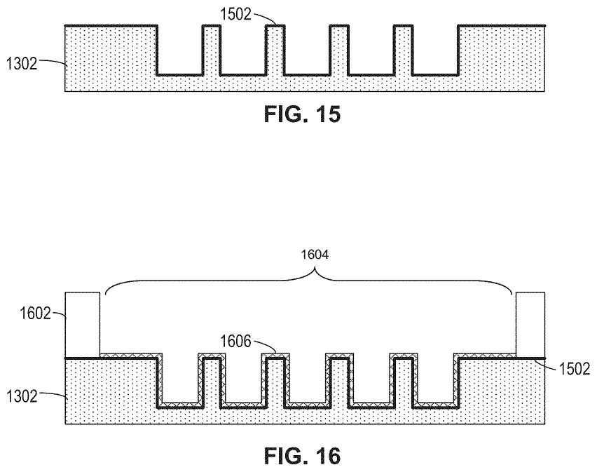

FIG. 8 is a cross-sectional side view of an example IC package 800 constructed in accordance with teachings disclosed herein. FIGS. 9 and 10 are respective bottom and top plan views of the example IC package 800 of FIG. 8. Unlike the batteries 103, 300, 604 of FIGS. 1-7, which are provided in one or more cavities corresponding to blind vias in the glass core 102, the example IC package 800 of FIGS. 8-10 includes batteries 802 provided in cavities 803 that extend through the glass core layer 102 from the first surface 114 to the second surface 118. That is, in the illustrated example of FIGS. 8-10, the cavities 803 correspond to through-glass-vias (TGVs). In FIG. 8, the cavities 803 are circular vias that extend from the first surface 114 to the second surface 118 along a longitudinal axis 804. The conductive layers 104, 106, 108, 110, 112 are disposed within the cavities 803 with each layer 104, 106, 108, 110, 112 extending through the cavities 803. In this example, the cathode current collector 112 extends along the longitudinal axis 804 and each subsequent layer 104, 106, 108, 110 circumferentially surrounds the other layers along the length of the cavities 803. As a result, the anode current collector 104 is adjacent walls of the cavities 803 and circumferentially surrounds each of the other layers 106, 108, 110, 112 along the longitudinal axis 804. In other examples, the ordering of the layers 104, 106, 108, 110, 112 is reversed such that the cathode current collector 112 is adjacent the walls of the cavities 803 and the anode current collector 104 extends along the longitudinal axis 804.

The batteries 802 are electrically coupled to the device 120 through conductive traces or routing 128. In particular, in this example, the separate batteries 802 are arranged in parallel with the anode current collector 104 of each battery 802 electrically coupled to one another and electrically coupled to the electrical device 120 by traces 128 extending therebetween along the first surface 114 of the glass core 102. As shown in FIGS. 8 and 10, the traces 128 are electrically coupled to the anode current collector 104 without extending across the cavities 803 so as to remain electrically isolated from the other layers 106, 108, 110, 112. More particularly, in some examples, the layers 106, 108, 110, 112 other than the anode current collector 104 are covered by a dielectric 122 at the end or opening of the cavities 803 (e.g., along the first surface 114) as shown in FIG. 8 In the illustrated example of FIGS. 8-10, the traces 128 are shown as extending directly adjacent the first surface 114 of the glass core 102. However, in other examples, the traces 128 may be separated from the glass core 102 by one or more layers of dielectric material (e.g., the dielectric 122). In such examples, the batteries 802 may be electrically coupled to the traces 128 through conductive vias extending through the dielectric layer(s).

Further, as shown in the illustrated example, the cathode current collectors 112 of the separate batteries 802 are electrically coupled to one another and electrically coupled to the electrical device 120 by traces 128 extending therebetween along the second surface 118 of the glass core 102. In this example, where cathode current collectors 112 extend along the longitudinal axis 804 of the batteries 802 and are surrounded by the anode current collector 104, the traces 128 connected to the cathode current collectors 112 necessarily need to cross over the paths of the anode current collectors 104 to connect to adjacent components beyond the outer circumference of the anode current collectors 104. Accordingly, to maintain electrical isolation between the anode current collector 104 and the cathode current collector 112, the traces 128 extend along the second surface 118 are not directly adjacent the surface 118 but separated therefrom by a dielectric 122. In the example IC package 800, the second surface 118 faces away from the electrical device 120. Accordingly, to enable the cathode current collectors 112 of the batteries 802 to be electrically coupled with the electrical device 120 through the traces 128, a separate through-glass via or plane (TGV, TGP) 806 extends through the glass core 102 with a first end electrically coupled to the traces 128 on the second surface 118 of the glass core 102 and a second end electrically coupled to the electrical device 120.

Turning to FIG. 9, the example IC package 800 is shown from a plan view of the second surface 118 including traces 128 extending continuously between different ones of the batteries 802. In the illustrated example of FIG. 9, the dielectric 122 is omitted to better illustrate the other components of the example IC package 800 in the plan view.

Turning to FIG. 10, the example IC package 800 is shown from a plan view of the first surface 114 including traces 128 extending continuously between different ones of the batteries 802. In the illustrated example of FIGS. 8-10, the traces 128 extend continuously between different ones of the anode current collectors 104 of the batteries 802 on the first side 114 of the glass core 102 while other traces 128 extend continuously between different ones of the cathode current collectors 112 of the batteries 802 on the second side 118 of the glass core 102, thereby placing the batteries 802 in parallel. In other examples, the traces 128 can electrically couple the anode current collectors 104 of ones of the batteries 802 to the cathode current collectors 112 of adjacent ones of the batters to place the batteries in series. While three batteries 802 are shown in the illustrated example of FIGS. 8-10, in other examples, any suitable number of batteries 802 may be implemented (e.g., 1, 2, 3, 4, 5, etc.). Further, while the batteries 802 are shown arranged in a straight line, the batteries 802 can be arranged in any configuration relative to one another. Additionally, while the cavities 803 used to house the batteries 802 are shown as having circular cross-sections, the cavities 803 can have any suitable cross-sectional shape (e.g., triangular, rectangular, etc.). In some examples, the cavities 803 are plane vias that extend through the glass core 102 in a direction substantially perpendicular to the first and second (e.g., top and bottom) surfaces 114, 118 of the glass core 102. In some such examples, the anode current collector 104 (or the cathode current collector 112) is deposited on both facing surfaces of the plane via with the other layers of battery 803 positioned therebetween.

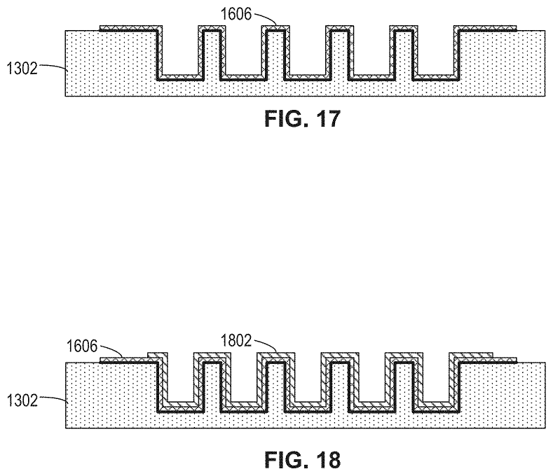

FIG. 11 is a flowchart representative of an example method 1100 to produce any one of the example IC packages 100, 400, 500, 600, 800 of FIGS. 1-10. FIGS. 12-24 represent the example IC packages at various stages during the fabrication process described in FIG. 11. Although the example method of manufacture is described with reference to the flowchart illustrated in FIG. 11, many other methods may alternatively be used. For example, the order of execution of the blocks may be changed, and/or some of the blocks described may be combined, divided, re-arranged, omitted, eliminated, and/or implemented in any other way.

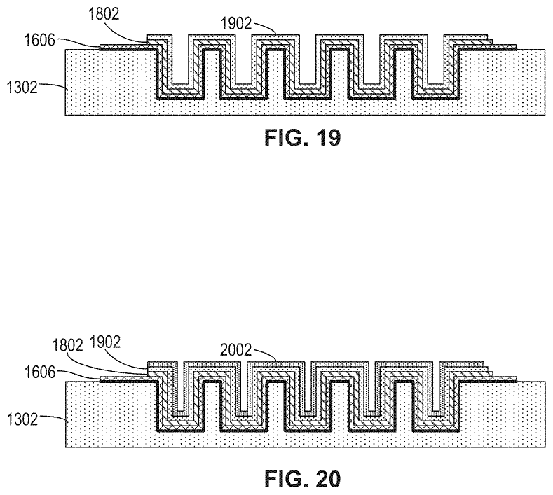

The example process of FIG. 11 begins at block 1102. The stage of fabrication following completion of block 1102 of FIG. 11 is represented in FIG. 13. At block 1102, a glass substrate 1302 is provided (e.g., as a raw glass substrate). In some examples, the glass substrate 1302 corresponds to the glass core 102 of FIGS. 1-10 prior to any laser drill or other processing operations. As shown in FIG. 13, the glass substrate 1302 includes a first surface 1304 (e.g., corresponding to the first surface 114 of FIGS. 1-10).

The stage of fabrication following completion of block 1104 of FIG. 11 is represented in FIG. 14. At block 1104, opening(s) 1402 are created in the glass substrate 1302. In some examples, the opening(s) 1402 correspond to the cavities 116 that are to house the embedded batteries 103, 300, 604, 802 shown and described in connection with FIGS. 1-10. Further, in some examples, the opening(s) 1402 also correspond to other through-glass vias (e.g., the TGV 806) in the glass substrate 1302. The openings 1402 can be created by laser assisted etching and/or drilling.

The stage of fabrication following completion of block 1106 of FIG. 11 is represented in FIG. 21 with FIGS. 15-21 representing various sub-stages detailed in connection with the flowchart of FIG. 12, which provides further detail regarding the implementation of block 1106. At block 1106, a series of materials 1606, 1802, 1902, 2002, 2102 to create a battery (e.g., any one of the batteries 103, 300, 604, 802) are deposited in the opening(s) 1402 in the glass substrate 1302. In some examples, the series of materials are deposited through use of lithography, direct printing methods (e.g., ink-jet, stencil printing, etc.), and/or chemical vapor deposition. In some examples, the materials 1606, 1802, 1902, 2002, 2102 are also deposited on the first surface 1304 of the glass substrate 1302. In some examples, the materials 1606, 1802, 1902, 2002, 2102 correspond to the anode current collector 104, the anode layer 106, the electrolyte 108, the cathode layer 110, and the cathode current collector 112, respectively.

The stage of fabrication following completion of block 1108 of FIG. 11 is represented in FIG. 22. At block 1108, a dielectric laminate 2202 is added over (e.g., deposited on) the battery and the first surface 1304 of the glass substrate 1302. In some examples, the dielectric laminate 2202 corresponds to the dielectric 122. In some examples, the dielectric laminate 2202 encloses the series of materials 1606, 1802, 1902, 2002, 2102 that correspond to the battery.

The stage of fabrication following completion of block 1110 of FIG. 11 is represented in FIG. 23. At block 1110, conductive interconnects 2302, 2304 are added to enable the electrical coupling of the battery (e.g., any one of the batteries 103, 300, 604, 802) to an electrical device (e.g., the electrical device 120). In some examples, the conductive interconnects 2302, 2304 correspond to the vias 124, 126 and/or the electrical traces or routing 128. In some examples, conductive interconnects 2302, 2304 are added between multiple layers of dielectric material. Thus, in some examples, the operations of block 1108 and 1110 may implemented through multiple iterations before advancing to block 1112.

The stage of fabrication following completion of block 1112 of FIG. 11 is represented in FIG. 24. At block 1112, an electrical device 2402 is electrically coupled to the conductive interconnects 2302, 2304. Thereafter, the example process of FIG. 11 ends and the final assembly may then proceed to additional fabrication processes as appropriate for the particular application in which the IC package is to be implemented.

As noted above, FIG. 12 is a flowchart representative of an example implementation of block 1106 of FIG. 11. The example process of FIG. 12 begins at block 1200. The stage of fabrication following completion of block 1200 of FIG. 12 is represented in FIG. 15. At block 1200, a metal seed layer 1502 is deposited on the glass substrate 1302. More particularly, in some examples, the metal seed layer 1502 can correspond to the anode current collector 104 and/or at least serves as a seed layer that may be subsequently plated to become the anode current collector 104 as discussed below in connection with block 1204.

The stage of fabrication following completion of block 1202 of FIG. 12 is not directly represented in the figures but can be understood with reference to FIG. 16, which represents completion of both block 1202 and 1204. At block 1202, a photoresist 1602 is deposited and patterned on the metal seed layer 1502. In some examples, the photoresist 1602 is patterned to define an opening 1604 that corresponds to the extent of the anode current collector 104 for the battery that is to be embedded in the glass substrate 1302. At block 1204, an anode current collector material 1606 is deposited. In some examples, the anode current collector material 1606 is deposited to the exposed surfaces of the metal seed layer 1502 through electroplating. That is, the anode current collector material 1606 is added to the metal seed layer 150 exposed within the opening 1604 of the patterned photoresist 1602. In some examples, the anode current collector material 1606 includes and/or is an extension of the metal seed layer 1502.

The stage of fabrication following completion of both blocks 1206 and 1208 of FIG. 12 is represented in FIG. 17. At block 1206, the photoresist 1602 is removed. At block 1208, exposed portions of the metal seed layer 1502 are etched. That is, the portions that were previously covered by the photoresist 1602 are etched and removed. As a result of the operations of blocks 1206 and 1208, only the anode current collector material 1606 (including the associated metal seed layer 1502) that is to serve as the anode current collector 104 remains on the glass substrate 1302.

The stage of fabrication following completion of block 1210 of FIG. 12 is represented in FIG. 18. At block 1210, an anode layer material 1802 is deposited. As shown in the illustrated example, the anode layer material 1802 is deposited on (e.g., overlaps) the anode current collector material 1606. The anode layer material 1802 can be deposited using any suitable technique (e.g., ink jet deposition, screen printing, standard lithography, etc.). In some examples, the anode layer material 1802 serves as the anode layer 106 in the battery 103, 300, 604, 802.

The stage of fabrication following completion of block 1212 of FIG. 12 is represented in FIG. 19. At block 1212, an electrolyte material 1902 (e.g., an electrolyte coated separator material) is deposited. As shown in the illustrated example, the electrolyte material 1902 is deposited on (e.g., overlaps) the anode layer material 1802. The electrolyte material 1902 can be deposited using any suitable technique (e.g., ink jet deposition, screen printing, standard lithography, etc.). In some examples, the electrolyte material 1902 serves as the electrolyte 108 in the battery 103, 300, 604, 802.

The stage of fabrication following completion of block 1214 of FIG. 12 is represented in FIG. 20. At block 1214, a cathode layer material 2002 is deposited. As shown in the illustrated example, the cathode layer material 2002 is deposited on (e.g., overlaps) the electrolyte material 1902. The cathode layer material 2002 can be deposited using any suitable technique (e.g., ink jet deposition, screen printing, lithography, etc.). In some examples, the cathode layer material 2002 serves as the cathode layer 110 in the battery 103, 300, 604, 802.

The stage of fabrication following completion of block 1216 of FIG. 12 is represented in FIG. 21. At block 1216, a cathode current collector material 2102 is deposited. As shown in the illustrated example, the cathode current collector material 2102 is deposited on (e.g., overlaps) the cathode layer material 2002. The cathode current collector material 2102 can be deposited using any suitable technique (e.g., ink jet deposition, screen printing, etc.). In some examples, the cathode current collector material 2102 serves as the cathode current collector 112 in the battery 103, 300, 604, 802.

Although the example method of implementing block 1106 of FIG. 11 is described with reference to the flowchart illustrated in FIG. 12, many other methods may alternatively be used. For example, the order of execution of the blocks may be changed, and/or some of the blocks described may be combined, divided, re-arranged, omitted, eliminated, and/or implemented in any other way. More particularly, in some examples, the metal seed layer 1502 can be added after adding the photoresist 1602. Further, in some examples, the photoresist 1602 can be removed after depositing at least one of the anode layer material 1802, the electrolyte material 1902, the cathode layer material 2002, and/or the cathode current collector material 2102.

Additionally or alternatively, in some examples, the series of materials 1606, 1802, 1902, 2002, 2102 can be deposited in an order different from the process described in FIG. 12. For example, the cathode current collector material 2102 can be deposited on the metal seed layer 1502, followed by the cathode layer material 2002, the electrolyte material 1902, the anode layer material 1802, and ending with the anode current collector material 1606.

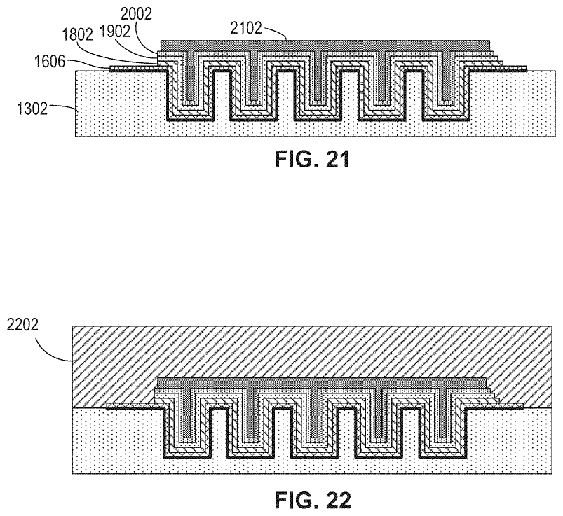

The example IC packages 100, 400, 500, 600, 800 disclosed herein may be included in any suitable electronic component. FIGS. 25-29 illustrate various examples of apparatus that may include any of the IC packages 100, 400, 500, 600, 800 disclosed herein.

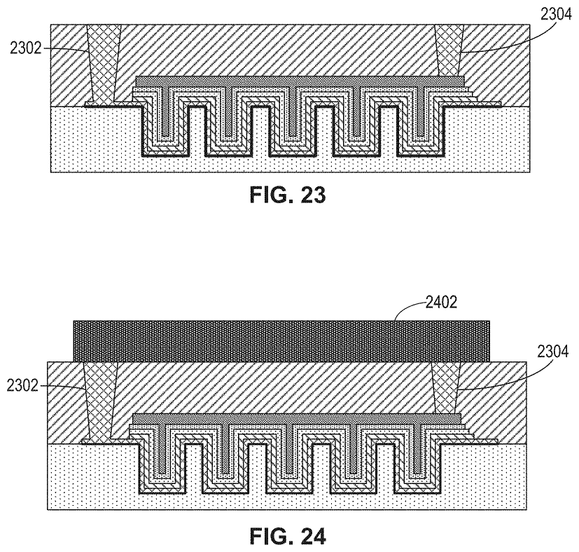

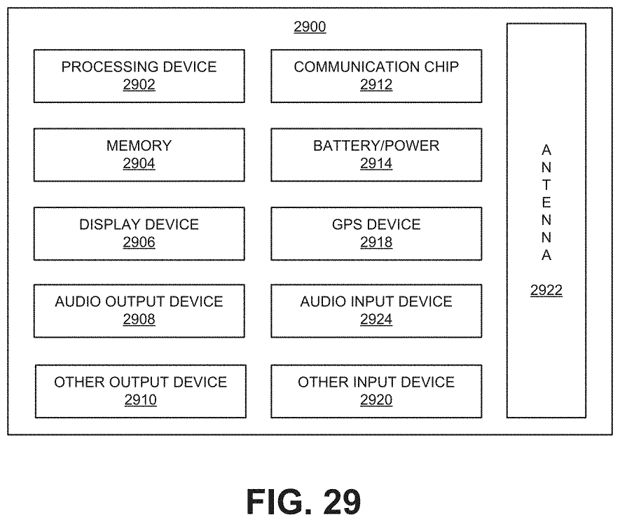

FIG. 25 is a top view of a wafer 2500 and dies 2502 that may be included in the example IC packages 100, 400, 500, 600, 800 of FIGS. 1-10. The wafer 2500 may be composed of semiconductor material and may include one or more dies 2502 having IC structures formed on a surface of the wafer 2500. Each of the dies 2502 may be a repeating unit of a semiconductor product that includes any suitable IC. After the fabrication of the semiconductor product is complete, the wafer 2500 may undergo a singulation process in which the dies 2502 are separated from one another to provide discrete “chips” of the semiconductor product. The die 2502 may include one or more transistors (e.g., some of the transistors 2640 of FIG. 26, discussed below) and/or supporting circuitry to route electrical signals to the transistors, as well as any other IC components. In some examples, the wafer 2500 or the die 2502 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 2502. For example, a memory array formed by multiple memory devices may be formed on a same die 2502 as a processing device (e.g., the processing device 2902 of FIG. 29) or other logic that is configured to store information in the memory devices or execute instructions stored in the memory array.

FIG. 26 is a cross-sectional side view of an IC device 2600 that may be included in the example IC packages 100, 400, 500, 600, 800. One or more of the IC devices 2600 may be included in one or more dies 2502 (FIG. 25). The IC device 2600 may be formed on a substrate 2602 (e.g., the wafer 2500 of FIG. 2) and may be included in a die (e.g., the die 2502 of FIG. 25). The substrate 2602 may be a semiconductor substrate composed of semiconductor material systems including, for example, n-type or p-type materials systems (or a combination of both). The substrate 2602 may include, for example, a crystalline substrate formed using a bulk silicon or a silicon-on-insulator (SOI) substructure. In some examples, the substrate 2602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the substrate 2602. Although a few examples of materials from which the substrate 2602 may be formed are described here, any material that may serve as a foundation for an IC device 2600 may be used. The substrate 2602 may be part of a singulated die (e.g., the dies 2502 of FIG. 25) or a wafer (e.g., the wafer 2500 of FIG. 25).

The IC device 2600 may include one or more device layers 2603 disposed on the substrate 2602. The device layer 2604 may include features of one or more transistors 2640 (e.g., metal oxide semiconductor field-effect transistors (MOSFETs)) formed on the substrate 2602. The device layer 2604 may include, for example, one or more source and/or drain (S/D) regions 2620, a gate 2622 to control current flow in the transistors 2640 between the S/D regions 2620, and one or more S/D contacts 2624 to route electrical signals to/from the S/D regions 2620. The transistors 2640 may include additional features not depicted for the sake of clarity, such as device isolation regions, gate contacts, and the like. The transistors 2640 are not limited to the type and configuration depicted in FIG. 26 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 2640 may include a gate 2622 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 2640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, and conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 2640 along the source-channel-drain direction, the gate electrode may consist of a U-shaped structure that includes a bottom portion substantially parallel to the surface of the substrate 2602 and two sidewall portions that are substantially perpendicular to the top surface of the substrate 2602. In other examples, at least one of the metal layers that form the gate electrode may simply be a planar layer that is substantially parallel to the top surface of the substrate 2602 and does not include sidewall portions substantially perpendicular to the top surface of the substrate 2602. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 2620 may be formed within the substrate 2602 adjacent to the gate 2622 of each transistor 2640. The S/D regions 2620 may be formed using an implantation/diffusion process or an etching/deposition process, for example. In the former process, dopants such as boron, aluminum, antimony, phosphorous, or arsenic may be ion-implanted into the substrate 2602 to form the S/D regions 2620. An annealing process that activates the dopants and causes them to diffuse farther into the substrate 2602 may follow the ion-implantation process. In the latter process, the substrate 2602 may first be etched to form recesses at the locations of the S/D regions 2620. An epitaxial deposition process may then be carried out to fill the recesses with material that is used to fabricate the S/D regions 2620. In some implementations, the S/D regions 2620 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 2620 may be formed using one or more alternate semiconductor materials such as germanium or a group III-V material or alloy. In further examples, one or more layers of metal and/or metal alloys may be used to form the S/D regions 2620.

Electrical signals, such as power and/or input/output (I/O) signals, may be routed to and/or from the devices (e.g., transistors 2640) of the device layer 2604 through one or more interconnect layers disposed on the device layer 2604 (illustrated in FIG. 26 as interconnect layers 2606-2610). For example, electrically conductive features of the device layer 2604 (e.g., the gate 2622 and the S/D contacts 2624) may be electrically coupled with the interconnect structures 2628 of the interconnect layers 2606-2610. The one or more interconnect layers 2606-2610 may form a metallization stack (also referred to as an “ILD stack”) 2619 of the IC device 2600.

The interconnect structures 2628 may be arranged within the interconnect layers 2606-2610 to route electrical signals according to a wide variety of designs (in particular, the arrangement is not limited to the particular configuration of interconnect structures 2628 depicted in FIG. 26). Although a particular number of interconnect layers 2606-2610 is depicted in FIG. 26, examples of the present disclosure include IC devices having more or fewer interconnect layers than depicted.

In some examples, the interconnect structures 2628 may include lines 2628a and/or vias 2628b filled with an electrically conductive material such as a metal. The lines 2628a may be arranged to route electrical signals in a direction of a plane that is substantially parallel with a surface of the substrate 2602 upon which the device layer 2604 is formed. For example, the lines 2628a may route electrical signals in a direction in and out of the page from the perspective of FIG. 26. The vias 2628b may be arranged to route electrical signals in a direction of a plane that is substantially perpendicular to the surface of the substrate 2602 upon which the device layer 2604 is formed. In some examples, the vias 2628b may electrically couple lines 2328a of different interconnect layers 2606-2610 together.

The interconnect layers 2606-2610 may include a dielectric material 2626 disposed between the interconnect structures 2628, as shown in FIG. 26. In some examples, the dielectric material 2626 disposed between the interconnect structures 2628 in different ones of the interconnect layers 2606-2610 may have different compositions; in other examples, the composition of the dielectric material 2626 between different interconnect layers 2606-2610 may be the same.

A first interconnect layer 2606 (referred to as Metal 1 or “M1”) may be formed directly on the device layer 2604. In some examples, the first interconnect layer 2606 may include lines 2628a and/or vias 2628b, as shown. The lines 2628a of the first interconnect layer 2606 may be coupled with contacts (e.g., the S/D contacts 2624) of the device layer 2604.

A second interconnect layer 2608 (referred to as Metal 2 or “M2”) may be formed directly on the first interconnect layer 2606. In some examples, the second interconnect layer 2608 may include vias 2628b to couple the lines 2628a of the second interconnect layer 2608 with the lines 2628a of the first interconnect layer 2606. Although the lines 2628a and the vias 2628b are structurally delineated with a line within each interconnect layer (e.g., within the second interconnect layer 2608) for the sake of clarity, the lines 2628a and the vias 2628b may be structurally and/or materially contiguous (e.g., simultaneously filled during a dual-damascene process) in some examples.

A third interconnect layer 2610 (referred to as Metal 3 or “M3”) (and additional interconnect layers, as desired) may be formed in succession on the second interconnect layer 2608 according to similar techniques and configurations described in connection with the second interconnect layer 2608 or the first interconnect layer 2606. In some examples, the interconnect layers that are “higher up” in the metallization stack 2619 in the IC device 2600 (i.e., further away from the device layer 2604) may be thicker.

The IC device 2600 may include a solder resist material 2634 (e.g., polyimide or similar material) and one or more conductive contacts 2636 formed on the interconnect layers 2606-2610. In FIG. 26, the conductive contacts 2636 are illustrated as taking the form of bond pads. The conductive contacts 2636 may be electrically coupled with the interconnect structures 2628 and configured to route the electrical signals of the transistor(s) 2640 to other external devices. For example, solder bonds may be formed on the one or more conductive contacts 2636 to mechanically and/or electrically couple a chip including the IC device 2600 with another component (e.g., a circuit board). The IC device 2600 may include additional or alternate structures to route the electrical signals from the interconnect layers 2606-2610; for example, the conductive contacts 2636 may include other analogous features (e.g., posts) that route the electrical signals to external components.

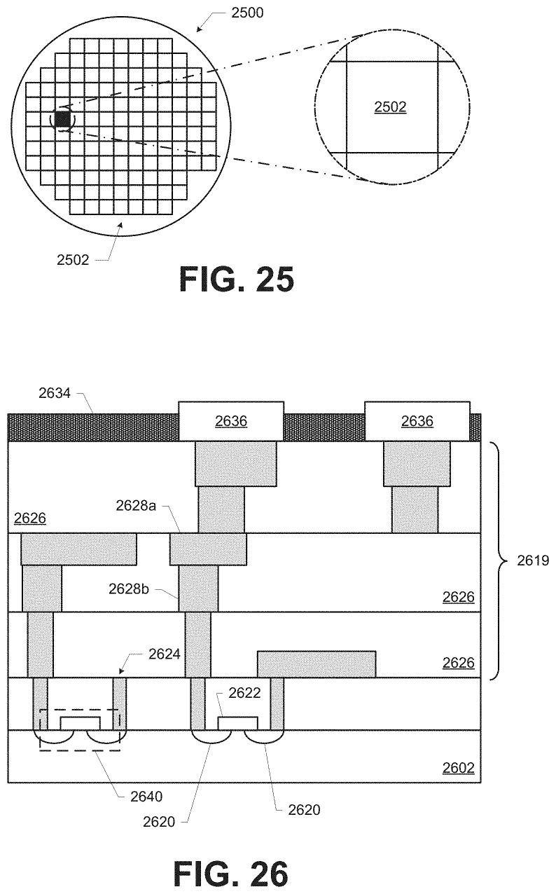

FIG. 27 is a cross-sectional view of an example IC package 2700 that may correspond to one or more of the example IC packages 100, 400, 500, 600, 800 disclosed herein. The package substrate 2702 may be formed of a dielectric material, and may have conductive pathways extending through the dielectric material between upper and lower faces 2722, 2724, or between different locations on the upper face 2722, and/or between different locations on the lower face 2724. These conductive pathways may take the form of any of the interconnects 2628 discussed above with reference to FIG. 26.

The IC package 2700 may include a die 2706 coupled to the package substrate 2702 via conductive contacts 2704 of the die 2706, first-level interconnects 2708, and conductive contacts 2710 of the package substrate 2702. The conductive contacts 2710 may be coupled to conductive pathways 2712 through the package substrate 2702, allowing circuitry within the die 2706 to electrically couple to various ones of the conductive contacts 2714 (or to other devices included in the package substrate 2702, not shown). The first-level interconnects 2708 illustrated in FIG. 27 are solder bumps, but any suitable first-level interconnects 2708 may be used. As used herein, a “conductive contact” may refer to a portion of conductive material (e.g., metal) serving as an electrical interface between different components; conductive contacts may be recessed in, flush with, or extending away from a surface of a component, and may take any suitable form (e.g., a conductive pad or socket).

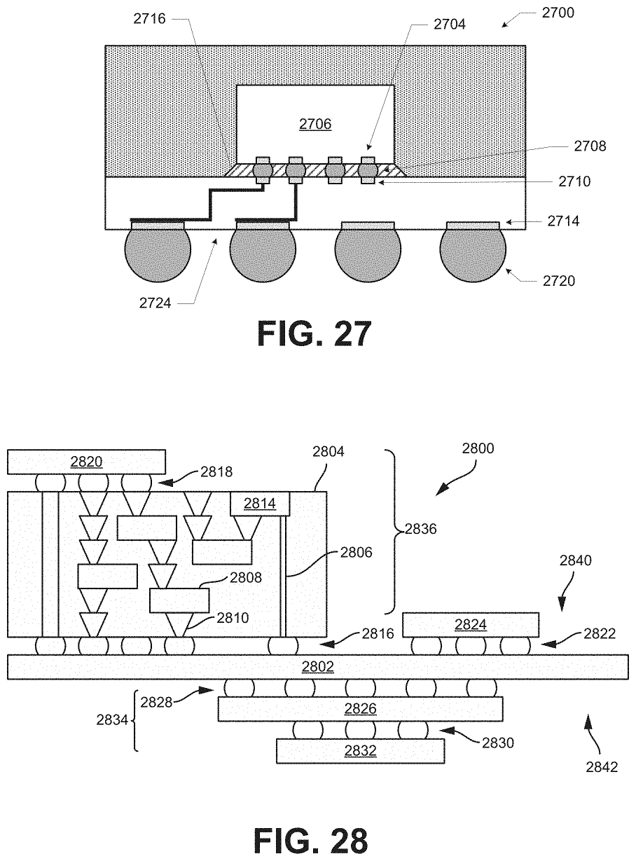

In some examples, an underfill material 2716 may be disposed between the die 2706 and the package substrate 2702 around the first-level interconnects 2708, and a mold compound 2718 may be disposed around the die 2706 and in contact with the package substrate 2702. In some examples, the underfill material 2716 may be the same as the mold compound 2718. Example materials that may be used for the underfill material 2716 and the mold compound 2718 are epoxy mold materials, as suitable. Second-level interconnects 2720 may be coupled to the conductive contacts 2714. The second-level interconnects 2720 illustrated in FIG. 27 are solder balls (e.g., for a ball grid array arrangement), but any suitable second-level interconnects 2720 may be used (e.g., pins in a pin grid array arrangement or lands in a land grid array arrangement). The second-level interconnects 2720 may be used to couple the IC package 2700 to another component, such as a circuit board (e.g., a motherboard), an interposer, or another IC package, as known in the art and as discussed below with reference to FIG. 28.

In FIG. 27, the IC package 2700 is a flip chip package. The die 2706 may take the form of any of the examples of the die 2502 discussed herein (e.g., may include any of the examples of the IC device 2600).

Although the IC package 2700 illustrated in FIG. 27 is a flip chip package, other package architectures may be used. For example, the IC package 2700 may be a ball grid array (BGA) package, such as an embedded wafer-level ball grid array (eWLB) package. In another example, the IC package 2700 may be a wafer-level chip scale package (WLCSP) or a panel fanout (FO) package. Although a single die 2706 is illustrated in the IC package 2700 of FIG. 27, an IC package 2700 may include multiple dies 2706. An IC package 2700 may include additional passive components, such as surface-mount resistors, capacitors, and inductors disposed on the first face 2722 or the second face 2724 of the package substrate 2702. More generally, an IC package 2700 may include any other active or passive components known in the art.

FIG. 28 is a cross-sectional side view of an IC device assembly 2800 that may include one or more of the example IC packages 100, 400, 500, 600, 800, in accordance with any of the examples disclosed herein. In some examples, the IC device assembly corresponds to one of the IC packages 100, 400, 500, 600, 800. The IC device assembly 2800 includes a number of components disposed on a circuit board 2802 (which may be, for example, a motherboard). The IC device assembly 2800 includes components disposed on a first face 2840 of the circuit board 2802 and an opposing second face 2842 of the circuit board 2802; generally, components may be disposed on one or both faces 2840 and 2842. Any of the IC packages discussed below with reference to the IC device assembly 2800 may take the form of any of the examples of the IC package 2700 discussed above with reference to FIG. 27 (e.g., may include one or more of the example IC packages 100, 400, 500, 600, 800).

In some examples, the circuit board 2802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2802. In other examples, the circuit board 2802 may be a non-PCB substrate.

The IC device assembly 2800 illustrated in FIG. 28 includes a package-on-interposer structure 2836 coupled to the first face 2840 of the circuit board 2802 by coupling components 2816. The coupling components 2816 may electrically and mechanically couple the package-on-interposer structure 2836 to the circuit board 2802, and may include solder balls (as shown in FIG. 28), male and female portions of a socket, an adhesive, an underfill material, and/or any other suitable electrical and/or mechanical coupling structure.

The package-on-interposer structure 2836 may include an IC package 2820 coupled to an interposer 2804 by coupling components 2818. The coupling components 2818 may take any suitable form for the application, such as the forms discussed above with reference to the coupling components 2816. Although a single IC package 2820 is shown in FIG. 28, multiple IC packages may be coupled to the interposer 2804; indeed, additional interposers may be coupled to the interposer 2804. The interposer 2804 may provide an intervening substrate used to bridge the circuit board 2802 and the IC package 2820. The IC package 2820 may be or include, for example, a die (the die 2502 of FIG. 25), an IC device (e.g., the IC device 2600 of FIG. 26), or any other suitable component. Generally, the interposer 2804 may spread a connection to a wider pitch or reroute a connection to a different connection. For example, the interposer 2804 may couple the IC package 2820 (e.g., a die) to a set of BGA conductive contacts of the coupling components 2816 for coupling to the circuit board 2802. In the example illustrated in FIG. 28, the IC package 2820 and the circuit board 2802 are attached to opposing sides of the interposer 2804; in other examples, the IC package 2820 and the circuit board 2802 may be attached to a same side of the interposer 2804. In some examples, three or more components may be interconnected by way of the interposer 2804.

In some examples, the interposer 2804 may be formed as a PCB, including multiple metal layers separated from one another by layers of dielectric material and interconnected by electrically conductive vias. In some examples, the interposer 2804 may be formed of an epoxy resin, a fiberglass-reinforced epoxy resin, an epoxy resin with inorganic fillers, a ceramic material, or a polymer material such as polyimide. In some examples, the interposer 2804 may be formed of alternate rigid or flexible materials that may include the same materials described above for use in a semiconductor substrate, such as silicon, germanium, and other group III-V and group IV materials. The interposer 2804 may include metal interconnects 2808 and vias 2810, including but not limited to through-silicon vias (TSVs) 2806. The interposer 2804 may further include embedded devices 2814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2804. The package-on-interposer structure 2836 may take the form of any of the package-on-interposer structures known in the art.

The IC device assembly 2800 may include an IC package 2824 coupled to the first face 2840 of the circuit board 2802 by coupling components 2822. The coupling components 2822 may take the form of any of the examples discussed above with reference to the coupling components 2816, and the IC package 2824 may take the form of any of the examples discussed above with reference to the IC package 2820.

The IC device assembly 2800 illustrated in FIG. 28 includes a package-on-package structure 2834 coupled to the second face 2842 of the circuit board 2802 by coupling components 2828. The package-on-package structure 2834 may include a first IC package 2826 and a second IC package 2832 coupled together by coupling components 2830 such that the first IC package 2826 is disposed between the circuit board 2802 and the second IC package 2832. The coupling components 2828, 2830 may take the form of any of the examples of the coupling components 2816 discussed above, and the IC packages 2826, 2832 may take the form of any of the examples of the IC package 2820 discussed above. The package-on-package structure 2834 may be configured in accordance with any of the package-on-package structures known in the art.

FIG. 29 is a block diagram of an example electrical device 2900 that may include one or more of the example IC packages 100, 400, 500, 600, 800, in accordance with any of the examples disclosed herein. For example, any suitable ones of the components of the electrical device 2900 may include one or more of the IC packages 2700, IC devices 2600, or dies 2502 disclosed herein. A number of components are illustrated in FIG. 29 as included in the electrical device 2900, but any one or more of these components may be omitted or duplicated, as suitable for the application. In some examples, some or all of the components included in the electrical device 2900 may be attached to one or more motherboards. In some examples, some or all of these components are fabricated onto a single system-on-a-chip (SoC) die.

Additionally, in various examples, the electrical device 2900 may not include one or more of the components illustrated in FIG. 29, but the electrical device 2900 may include interface circuitry for coupling to the one or more components. For example, the electrical device 2900 may not include a display device 2906, but may include display device interface circuitry (e.g., a connector and driver circuitry) to which a display device 2906 may be coupled. In another set of examples, the electrical device 2900 may not include an audio input device 2924 or an audio output device 2908, but may include audio input or output device interface circuitry (e.g., connectors and supporting circuitry) to which an audio input device 2924 or audio output device 2908 may be coupled.

The electrical device 2900 may include a processing device 2902 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 2900 may include a memory 2904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2904 may include memory that shares a die with the processing device 2902. This memory may be used as cache memory and may include embedded dynamic random access memory (eDRAM) or spin transfer torque magnetic random access memory (STT-MRAM).

In some examples, the electrical device 2900 may include a communication chip 2912 (e.g., one or more communication chips). For example, the communication chip 2912 may be configured for managing wireless communications for the transfer of data to and from the electrical device 2900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2612 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2912 may operate in accordance with other wireless protocols in other examples. The electrical device 2900 may include an antenna 2922 to facilitate wireless communications and/or to receive other wireless communications (such as AM or FM radio transmissions).

In some examples, the communication chip 2912 may manage wired communications, such as electrical, optical, or any other suitable communication protocols (e.g., the Ethernet). As noted above, the communication chip 2912 may include multiple communication chips. For instance, a first communication chip 2912 may be dedicated to shorter-range wireless communications such as Wi-Fi or Bluetooth, and a second communication chip 2912 may be dedicated to longer-range wireless communications such as global positioning system (GPS), EDGE, GPRS, CDMA, WiMAX, LTE, EV-DO, or others. In some examples, a first communication chip 2912 may be dedicated to wireless communications, and a second communication chip 2912 may be dedicated to wired communications.

The electrical device 2900 may include battery/power circuitry 2914. The battery/power circuitry 2614 may include one or more energy storage devices (e.g., batteries or capacitors) and/or circuitry for coupling components of the electrical device 2900 to an energy source separate from the electrical device 2900 (e.g., AC line power).

The electrical device 2900 may include a display device 2906 (or corresponding interface circuitry, as discussed above). The display device 2906 may include any visual indicators, such as a heads-up display, a computer monitor, a projector, a touchscreen display, a liquid crystal display (LCD), a light-emitting diode display, or a flat panel display.

The electrical device 2900 may include an audio output device 2908 (or corresponding interface circuitry, as discussed above). The audio output device 2908 may include any device that generates an audible indicator, such as speakers, headsets, or earbuds.

The electrical device 2900 may include an audio input device 2924 (or corresponding interface circuitry, as discussed above). The audio input device 2924 may include any device that generates a signal representative of a sound, such as microphones, microphone arrays, or digital instruments (e.g., instruments having a musical instrument digital interface (MIDI) output).

The electrical device 2900 may include a GPS device 2918 (or corresponding interface circuitry, as discussed above). The GPS device 2918 may be in communication with a satellite-based system and may receive a location of the electrical device 2900, as known in the art.

The electrical device 2900 may include any other output device 2910 (or corresponding interface circuitry, as discussed above). Examples of the other output device 2910 may include an audio codec, a video codec, a printer, a wired or wireless transmitter for providing information to other devices, or an additional storage device.

The electrical device 2900 may include any other input device 2920 (or corresponding interface circuitry, as discussed above). Examples of the other input device 2920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2900 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 2900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

Example 1 includes an apparatus comprising a glass core layer having opposing first and second surfaces, the glass core layer including a cavity extending from the first surface toward the second surface, and a battery including a first conductive material positioned in the cavity, a second conductive material positioned in the cavity, and an electrolyte to separate the first conductive material from the second conductive material.

Example 2 includes the apparatus of example 1, wherein the first conductive material corresponds to an anode current collector of the battery and the second conductive material corresponds to a cathode current collector of the battery, the battery further including an anode layer between the anode current collector and the electrolyte, and a cathode layer between the cathode current collector and the electrolyte.

Example 3 includes the apparatus of example 2, wherein the electrolyte is a solid state electrolyte that enables ion diffusion between the anode layer and the cathode layer.

Example 4 includes the apparatus of example 1, wherein the first conductive material is positioned on and extends across a surface of the cavity in the glass core layer.

Example 5 includes the apparatus of example 4, wherein the surface of the cavity corresponds to a wall of the cavity, the wall extending in a direction transverse to the first surface of the glass core layer, the second conductive material positioned within the cavity such that the first conductive material on the wall of the cavity surrounds the second conductive material.

Example 6 includes the apparatus of example 1, wherein the cavity is one of multiple cavities in the glass core layer, the multiple cavities distributed along the first surface of the glass core layer with different ones of the multiple cavities separated by portions of the glass core layer, the first conductive material positioned in different ones of the multiple cavities.

Example 7 includes the apparatus of example 6, wherein the first conductive material extends between the different ones of the multiple cavities over the first surface of the glass core layer.

Example 8 includes the apparatus of example 7, wherein the second conductive material is to cover the first conductive material in the different ones of the multiple cavities, the second conductive material to extend continuously in a straight line across the different ones of the multiple cavities.

Example 9 includes the apparatus of example 6, wherein the battery is a first battery, the apparatus further including a second battery, the first battery associated with a first one of the multiple cavities and the second battery associated with a second one of the multiple cavities.

Example 10 includes the apparatus of example 9, wherein the first battery is electrically coupled to the second battery in series.

Example 11 includes the apparatus of example 9, wherein the first battery is electrically coupled to the second battery in parallel.

Example 12 includes the apparatus of example 1, wherein the cavity extends through the glass core layer from the first surface to the second surface.

Example 13 includes the apparatus of example 12, wherein the cavity is defined by a circular via including a longitudinal axis extending from the first surface to the second surface, the first conductive material circumferentially surrounding the second conductive material along the longitudinal axis.

Example 14 includes an integrated circuit (IC) package comprising a substrate including a glass core, an electrical device supported by the substrate, and a battery embedded in the glass core, the battery electrically coupled to the electrical device.

Example 15 includes the battery of example 14, wherein the battery includes a series of layers of materials disposed within an opening in the glass core, the series of layers of materials including at least one of an anode current collector, an anode layer, an electrolyte layer, a cathode layer, or a cathode current collector.

Example 16 includes the battery of example 15, wherein the glass core includes a first surface and a second surface opposite the first surface, the series of layers of materials to overlap one another on the first surface of the glass core.

Example 17 includes the battery of example 14, wherein the glass core includes an opening extending into the glass core from a first surface of the glass core, the first surface facing toward the electrical device, the battery disposed within the opening.

Example 18 includes the battery of example 17, wherein the opening extends through the glass core from the first surface to a second surface of the glass core, the second surface facing away from the electrical device, the electrical device electrically coupled to a first one of an anode of the battery or a cathode of the battery at the first surface of the glass core, the electrical device electrically coupled, through a conductive via extending through the glass core, to a second one of the anode or the cathode at the second surface of the glass core.

Example 19 includes the battery of example 14, wherein the glass core includes multiple openings spaced apart along a first surface of the glass core, a first one of an anode or a cathode of the battery lining walls of different ones of the openings, the first one of the anode or the cathode to be electrically coupled across the different ones of the openings by extending across the first surface of the glass core.

Example 20 includes the battery of example 19, wherein a second one of the anode or the cathode is positioned within the multiple openings between portions of the first one of the anode or the cathode lining the walls of the different ones of the openings.

Example 21 includes a method for manufacturing an integrated circuit (IC) package with an embedded battery, the method comprising forming a cavity in a glass substrate, and depositing a series of materials in successive layers within the cavity, the series of materials arranged to define the battery, the series of materials including an anode layer material, an electrolyte, and a cathode layer material, the electrolyte positioned between the anode layer material and the cathode layer material.

Example 22 includes the method of example 21, wherein the cavity is a via that extends through the glass substrate.

Example 23 includes the method of example 21, further including depositing a dielectric laminate to enclose the series of materials.

Example 24 includes the method of example 21, wherein the forming of the cavity includes forming multiple cavities in the glass substrate, the depositing of the series of materials includes depositing the series of materials in different ones of the multiple cavities.

Example 25 includes the method of example 21, further including attaching a semiconductor device to the glass substrate, and electrically coupling the semiconductor device to the battery.

From the foregoing, it will be appreciated that example systems, methods, apparatus, and articles of manufacture have been disclosed that enable integrated circuit packaged to embed batteries within glass substrates and/or cores. Embedding batteries within a package substrate based on thin film battery technology eliminates the need for large and/or bulky batteries or associated electrical connections to be added on the surface of the substrate, which can take up space on the surface of the substrate, thereby leading to the need for packages with larger footprints. Further, embedding batteries within a glass core of a package substrate mitigates against concerns associated with high temperature fabrication processes because of the improved material properties of glass relative to traditional organic cores.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

What is claimed is:

1. An apparatus comprising:
a glass core layer having opposing first and second surfaces, the glass core layer including a cavity extending from the first surface toward the second surface; and
a battery including:
a first conductive material positioned in the cavity;
a second conductive material positioned in the cavity; and
an electrolyte to separate the first conductive material from the second conductive material.

2. The apparatus of claim 1, wherein the first conductive material corresponds to an anode current collector of the battery and the second conductive material corresponds to a cathode current collector of the battery, the battery further including:
an anode layer between the anode current collector and the electrolyte; and
a cathode layer between the cathode current collector and the electrolyte.

3. The apparatus of claim 2, wherein the electrolyte is a solid state electrolyte that enables ion diffusion between the anode layer and the cathode layer.

4. The apparatus of claim 1, wherein the first conductive material is positioned on and extends across a surface of the cavity in the glass core layer.

5. The apparatus of claim 4, wherein the surface of the cavity corresponds to a wall of the cavity, the wall extending in a direction transverse to the first surface of the glass core layer, the second conductive material positioned within the cavity such that the first conductive material on the wall of the cavity surrounds the second conductive material.

6. The apparatus of claim 1, wherein the cavity is one of multiple cavities in the glass core layer, the multiple cavities distributed along the first surface of the glass core layer with different ones of the multiple cavities separated by portions of the glass core layer, the first conductive material positioned in different ones of the multiple cavities.

7. The apparatus of claim 6, wherein the first conductive material extends between the different ones of the multiple cavities over the first surface of the glass core layer.

8. The apparatus of claim 7, wherein the second conductive material is to cover the first conductive material in the different ones of the multiple cavities, the second conductive material to extend continuously in a straight line across the different ones of the multiple cavities.

9. The apparatus of claim 6, wherein the battery is a first battery, the apparatus further including a second battery, the first battery associated with a first one of the multiple cavities and the second battery associated with a second one of the multiple cavities.

10. The apparatus of claim 9, wherein the first battery is electrically coupled to the second battery in series.

11. The apparatus of claim 9, wherein the first battery is electrically coupled to the second battery in parallel.

12. The apparatus of claim 1, wherein the cavity extends through the glass core layer from the first surface to the second surface.

13. The apparatus of claim 12, wherein the cavity is defined by a circular via including a longitudinal axis extending from the first surface to the second surface, the first conductive material circumferentially surrounding the second conductive material along the longitudinal axis.

14. An integrated circuit (IC) package comprising:
a substrate including a glass core;
an electrical device supported by the substrate; and
a battery embedded in the glass core, the battery electrically coupled to the electrical device.

15. The battery of claim 15, wherein the battery includes a series of layers of materials disposed within an opening in the glass core, the series of layers of materials including at least one of an anode current collector, an anode layer, an electrolyte layer, a cathode layer, or a cathode current collector.

16. The battery of claim 16, wherein the glass core includes a first surface and a second surface opposite the first surface, the series of layers of materials to overlap one another on the first surface of the glass core.

17. The battery of claim 15, wherein the glass core includes an opening extending into the glass core from a first surface of the glass core, the first surface facing toward the electrical device, the battery disposed within the opening.

18. The battery of claim 18, wherein the opening extends through the glass core from the first surface to a second surface of the glass core, the second surface facing away from the electrical device, the electrical device electrically coupled to a first one of an anode of the battery or a cathode of the battery at the first surface of the glass core, the electrical device electrically coupled, through a conductive via extending through the glass core, to a second one of the anode or the cathode at the second surface of the glass core.

19. The battery of claim 15, wherein the glass core includes multiple openings spaced apart along a first surface of the glass core, a first one of an anode or a cathode of the battery lining walls of different ones of the openings, the first one of the anode or the cathode to be electrically coupled across the different ones of the openings by extending across the first surface of the glass core.

20. The battery of claim 20, wherein a second one of the anode or the cathode is positioned within the multiple openings between portions of the first one of the anode or the cathode lining the walls of the different ones of the openings.

21. A method for manufacturing an integrated circuit (IC) package with an embedded battery, the method comprising:
forming a cavity in a glass substrate; and
depositing a series of materials in successive layers within the cavity, the series of materials arranged to define the battery, the series of materials including an anode layer material, an electrolyte, and a cathode layer material, the electrolyte positioned between the anode layer material and the cathode layer material.

22. The method of claim 22, wherein the cavity is a via that extends through the glass substrate.

23. The method of claim 22, further including depositing a dielectric laminate to enclose the series of materials.

24. The method of claim 22, wherein the forming of the cavity includes forming multiple cavities in the glass substrate, the depositing of the series of materials includes depositing the series of materials in different ones of the multiple cavities.

25. The method of claim 22, further including:
attaching an electrical device to the glass substrate; and
electrically coupling the electrical device to the battery.
